(19) United States
(12) Patent Application Publication
(10) Pub. No.: US 2017/0336152 A1
(43) Pub. Date: Nov. 23, 2017

(54) DOUBLE-SIDED COOLER FOR COOLING BOTH SIDES OF ELECTRONIC COMPONENT

(71) Applicant: Hyundai Motor Company, Seoul (KR)

(72) Inventors: Sang Chan Jeong, Seoul (KR); Jung Hong Joo, Suwon (KR); Moon Jo Kang, Seoul (KR)

(21) Appl. No.: 15/248,483

(22) Filed: Aug. 26, 2016

(30) Foreign Application Priority Data
May 20, 2016 (KR) 10-2016-0062132

(51) Int. Cl. F28F 13/12; F28F 1/40; F28F 13/08; H05K 7/20; F28D 15/00; F28D 21/00

(52) U.S. Cl. CPC F28F 13/12; H05K 7/20281; H05K 7/20272; H05K 7/20254; F28D 15/00; F28F 1/40; F28F 13/08; F28D 2021/0028

(57) ABSTRACT

A double-sided cooler for cooling both sides of a component where heat is generated includes: a plurality of radiating parts including a plurality of cooling channels through which a coolant flows, the radiating parts being adhered to first and second sides of the component, respectively, and a hollow connection part for mixing the coolant discharged from the cooling channels of one radiating part adhered to the first side of the component to supply the mixed coolant to the cooling channels of another radiating part adhered to the second side of the component, the connection part continuously formed from each radiating part to have the same shape of each radiating part to minimize pressure loss.

### CROSS-REFERENCE TO RELATED APPLICATION

This application claims under 35 U.S.C. §119(a) the benefit of Korean Patent Application No. 10-2016-0062132, filed on May 20, 2016 in the Korean Intellectual Property Office, the entire contents of which are incorporated by reference herein.

### BACKGROUND

### 1. Technical Field

The present invention relates to a double-sided cooler, and more particularly, to a double-sided cooler for cooling both sides of a component where heat is generated.

### 2. Description of the Related Art

An inverter module, a capacitor and a power converter, such as a DC-DC converter module, are electronic components where heat is generated, and thus require cooling in different applications.

To this end, conventionally, a case type cooler is used. Radiating pins are formed at an outside of the case type cooler, and an inner surface of the case type cooler is adhered to one surface of a component, and as such, heat generated from the component may be radiated outside.

However, in the case type cooler, the surface adhered to the component is limited to one surface, and as such, a cooling area is small. Further, since the component is disposed on one plane, a layout of the component is limited. In addition, in order to secure a minimum strength of the case type cooler, the case type cooler needs to have a thickness of 3 mm or more, each radiating pin needs to have a thickness of 10 mm or more, and as such, there is a problem that weight of the entire package is increased.

Thus, a cooler which may cool both sides of the component and may improve cooling efficiency due to reduction of temperature difference upon a cooling process, may be necessary.

### SUMMARY

It is an object of the present invention to provide a cooler capable of improving cooling efficiency due to reduction of coolant temperature difference between cooling channels.

In accordance with one aspect of the present invention, the above and other objects can be accomplished by the provision of a double-sided cooler for cooling both sides of a component including a plurality of radiating parts including a plurality of cooling channels where a coolant flows, the radiating parts adhered to a first side and a second side of the component, respectively, and a hollow connection part for mixing the coolant discharged from the cooling channels of one radiating part adhered to the first side of the component to supply the mixed coolant to the cooling channels of another radiating part adhered to the second side of the component, the connection part continuously formed from each radiating part to have the same shape of each radiating part to minimize pressure loss.

Each of the radiating parts may include a hollow radiating pipe adhered to the first or second sides of the component, and radiating plates dividing an inner space of the radiating pipe to form the cooling channels in a longitudinal direction of the radiating pipe.

Each radiating plate may be formed to be integrated with the radiating pipe and is formed to be perpendicular to a contact surface between the radiating pipe and component.

The radiating plate may be formed to have a concave-convex shape by a repetition of an upper plate, a vertical plate and a lower plate, the radiating plate may be inserted into the radiating pipe, the upper and lower plates adhered to upper and lower surfaces in the radiating pipe, respectively, and each cooling channel may be formed between the adjacent vertical plates.

The radiating plate may be formed in a meandering bent shape to have a lateral zigzag shape in a longitudinal direction in order to increase a contact area for the coolant.

The vertical plate may be formed to have a plurality of flow holes for the coolant to flow between each cooling channel.

The double-sided cooling may further include a coolant supply including a supply pipe receiving a cold coolant from a heat exchanger and a supply header supplying the coolant supplied from the supply pipe to the cooling channels of the radiating parts, and a coolant discharger including a discharge header receiving the heated coolant from the radiating parts and a discharge pipe transferring the coolant supplied from the discharge header to the heat exchanger.

A plurality of the components may be arranged in a multilayer structure, the radiating parts may be arranged between the components and on an outside of an outermost component, the radiating parts may be connected to one another in series through a plurality of the connection parts, and the coolant supply and coolant discharger may be connected to both ends of the radiating parts connected to one another in series.

The connection part may be formed to have a plurality of protrusions and a plurality of grooves to generate vortex flow of the coolant introduced into the connection part and to mix the coolant.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view illustrating a layout of a double-sided cooler according to an embodiment of the present invention;

FIG. 2 is a view illustrating generation of temperature difference of cooling channels in accordance with heat difference generated from a component;

FIG. 3 is a view illustrating a radiating pipe according to an embodiment of the present invention;

FIG. 4 is a view illustrating a radiating pipe according to another embodiment of the present invention;

FIG. 5 is a partially cut-away perspective view illustrating a connection part having protrusions and grooves therein according to an embodiment of the present invention;

FIG. 6 is a sectional view illustrating the connection part having the protrusions and grooves therein according to the illustrated embodiment of the present invention; and

FIG. 7 is a perspective view illustrating a layout of a double-sided cooler according to another embodiment of the present invention.

### DETAILED DESCRIPTION OF THE PREFERRED EMBODIMENTS

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Further, the control logic of the present invention may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Hereinafter, a double-sided cooler for cooling both sides of an electronic component in accordance with an exemplary embodiment of the present invention will be described with reference to the accompanying drawings.

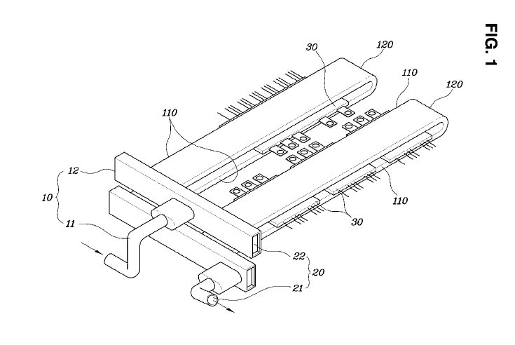

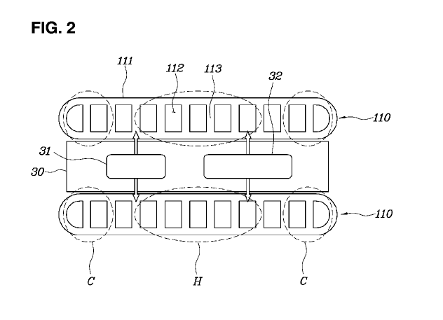

As illustrated in FIGS. 1 and 2, according to the present invention, a double-sided cooler for components 30 where heat is generated, may mainly be divided into radiating parts 110 and connection parts 120.

Each radiating part 110 includes a plurality of cooling channels 112 separated by radiating plates 113 while being disposed in a radiating pipe 111 formed to have a plate-type tube or pipe. Each cooling channel 112 is longitudinally formed in a direction parallel to a flow direction of a coolant. Accordingly, as the coolant flows through the cooling channels 112, cooling efficiency of the radiating parts 110 may be improved.

The radiating parts 110 are disposed at both sides of each component 30. The radiating parts 110 are adhered to opposite first and second sides (i.e., one side and the other side of the component 30, respectively) to absorb heat generated by the component 30. Each radiating part 110 may be directly in contact with the component 30, or may be in contact with the component 30 through a thermal grease and so on.

As the coolant, which flows in the radiating parts 110, passes through different flow paths of the cooling channels 112 formed in the radiating parts 110, the coolant absorbs heat of the components 30.

In this case, an amount of heat generated by the component 30 is different from each position of the component 30, so that a different amount of heat is applied to each cooling channel 112.

For example, a greater amount of heat amount is applied to the cooling channels 112 corresponding to a central part of each component 30, where a heat source is densely disposed so that it is difficult to radiate heat. The coolant flowing in the cooling channels 112 corresponding to the central part of the component 30 is heated to a higher temperature than the coolant flowing in the cooling channels 112 corresponding to an edge part of the component 30.

In detail, the central part of the component 30 is a part in which a heat source, for example, a diode 31 and an insulated gate bipolar transistor (IGBT), and so on, is densely disposed. The coolant flowing in a high temperature region H corresponding to the central part of the component 30 is heated to a high temperature since heat is densely generated from a heat source.

Otherwise, since a low temperature region C corresponding to the edge part of the component 30 is separated from a heat source disposed in the component 30 and it is relatively easy to dissipate heat outside, the coolant flowing in the low temperature region C is maintained at a low temperature.

Accordingly, in the present invention, the coolant differentially heated for each cooling channel 112 is mixed at the connection parts 120 to uniformly adjust temperature of the coolant, and then is supplied to the following radiating part 110, and as such, cooling efficiency is improved.

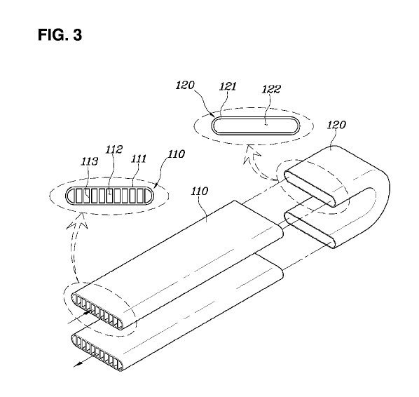

As illustrated in FIGS. 1 and 3, each connection part 120 is connected between a pair of radiating parts 110 disposed at both sides of one component 30. Each connection part 120 functions as an intermediary of the coolant which flows through one connection part 120 to another connection part 120.

When the cooling channels 112 are formed in the connection parts 120 and the flow paths are separated in the connection parts 120, the coolant flowing in the central part while absorbing more heat may be maintained at a high temperature, and as such, cooling efficiency of the central part of the component 30 may be decreased.

Accordingly, the cooling channels 112 are not formed in the connection parts 120, and each connection part 120 is formed to have a connection pipe 121 which continuously extends from the corresponding radiating pipe 111. Each connection pipe 121 is bent to be connected to ends of a pair of radiating pipes 111. A mixed space 122 is formed in each connection pipe 121.

A sectional shape of each radiating pipe 111 except for the radiating plates 113 may be the same as an inner shape of each connection pipe 121. As the above same shapes of the radiating pipe 111 and connection pipe 121 are continuously formed, pressure variation may be minimized upon coolant flow. Since pressure loss of the coolant is minimized, energy required for circulating the coolant may be reduced.

In detail, when the coolant is stored to be mixed in a kind of pipe having a smaller diameter than each radiating pipe 111 or a chamber, reduction of temperature difference due to mixture of coolant may be more effective. However, as an area where the coolant flows largely changes, flow speed and pressure of the coolant change. As a result, this leads to pressure loss of the coolant.

When pressure of the coolant is decreased, there is a problem that energy consumed at a pump for circulating the coolant is increased, and as such, a circle of low cooling efficiency due to high energy consumption may be encountered.

Accordingly, an inner area of each connection pipe 121 is similar to an inner area of each radiating pipe 111. To this end, it is necessary for the connection pipe 121 to be continuously formed from the radiating pipe 111.

As illustrated in FIGS. 2 and 3, the radiating plates 113 are formed to be integrated with each radiating pipe 111. The radiating plates 113 are mounted to be perpendicular to a contact surface between the corresponding component 30 and radiating pipe 111 and, as such, the radiating plates 113 divide an inner space of the corresponding radiating pipe 111. The divided inner spaces of each radiating pipe 111 are formed as the cooling channels 112. When each radiating plate 113 is mounted to be perpendicular to the contact surface, a length of the radiating plate 113 is minimized, and as such, heat may be smoothly transferred from one surface to the other surface of each radiating pipe 111.

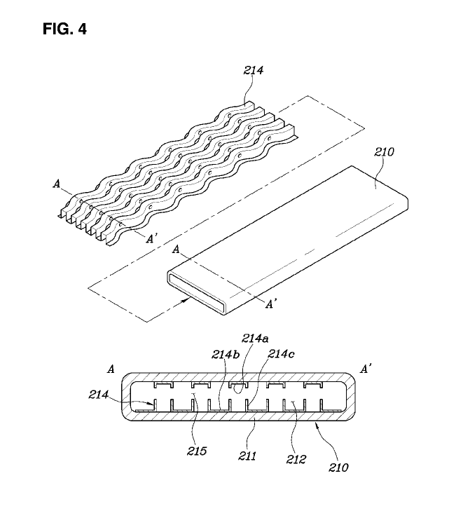

According to another embodiment of the present invention, as illustrated in FIG. 4, a radiating part 210 may be manufactured by inserting a radiating plate 214 which is separately manufactured, into a radiating pipe 211.

That is, the radiating plate 214 is manufactured to include upper plates 214a, lower plates 214b, and vertical plates 214c to have a concave-convex shape. The upper and lower plates 214a and 214b for receiving heat are adhered to inner surfaces of the radiating pipe 210, respectively. The upper plates 214a and the lower plates 214b are connected through the vertical plates 214c, respectively. In this case, each of cooling channels 212 is formed between two adjacent vertical plates 214c such that the coolant flows through the cooling channels 212.

The radiating plate 214 may be formed in a meanderingly bent shape to have a lateral zigzag shape in a longitudinal direction. A contact area between the coolant and the radiating plate 214 is increased by the above shape, and as such, radiating efficiency may be more improved.

Further, a plurality of flow holes 215 may be formed at each vertical plate 214c of the radiating plate 214. The coolant flows through the flow holes 215 between each cooling channel 212 and, as such, the coolant may be mixed. Temperature difference of the coolant for each cooling channel 212 may be reduced through the above structure, even before mixing the coolant at the connection parts 120.

The inner surface of the connection pipe 121 of each connection part 120 may be smoothly formed. Alternatively, a structure for smoothly mixing the coolant may be embedded in each connection pipe 121.

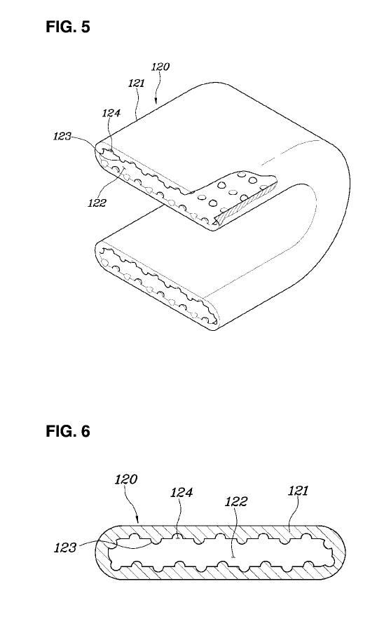

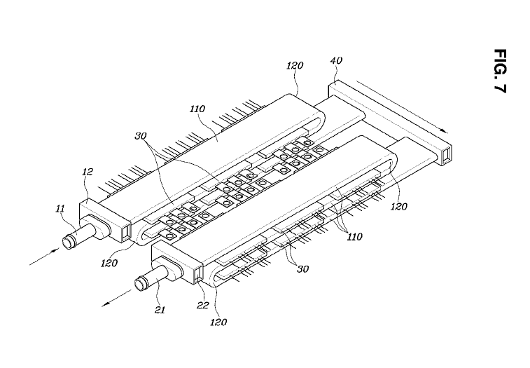

In an example, as illustrated in FIGS. 5 and 6, protrusions and grooves may be formed at the inner surface of each connection pipe 121. Vortex flow of the coolant is generated through the protrusions and grooves and, as such, the coolant may be effectively mixed.

As illustrated in FIG. 1, supply and discharge structures for the coolant may be further provided at the radiating parts 110 and connection parts 120.

In detail, a coolant supply 10 including a supply pipe 11 and a supply header 12 for transferring a cold coolant from a heat exchanger (not shown) and a coolant discharger 20 including a discharge header 22 for receiving the heated coolant from the radiating parts 110 and a discharge pipe 21 for transferring the coolant from the discharge header 22 to the heat exchanger.

The components 30 may be configured to have a single layer, or to have multiple layers.

As illustrated in FIG. 7, when the components 30 are configured to have multiple layers, the radiating parts 110 are disposed between the components 30 and on an outside of an outermost component 30. The adjacent radiating parts 110 are connected to each connection part 120. In this case, the connection parts 120 are connected to the radiating parts 110 in a zigzag manner, respectively, and, as such, the entire radiating parts 110 may be connected to form one flow path.

The coolant passing through each radiating part 110 is mixed at the connection parts 120, and then is supplied to the following radiating part 110, and as such, temperature of the coolant is uniform. As a result, cooling efficiency may be increased.

In addition, as illustrated in FIG. 1, the coolant supply 10 and coolant discharger 20 may be arranged up and down in a parallel manner, whereas, when an odd number of radiating parts 110 is provided, the coolant supply 10 and coolant discharger 20 may be arranged in opposite directions. As illustrated in FIG. 7, the coolant supply 10 and coolant discharger 20 may be separately mounted and two sets of coolers may be connected through a connection header 40.

As apparent from the above description, in accordance with the present invention, the double-sided cooler has the following effects.

First, the components are stacked in multiple layers and, as such, volume of a package may be reduced.

Second, coolant temperature difference for each cooling channel is decreased and, as such, cooling efficiency may be improved.

Third, the protrusions and grooves are formed at each connection part and, as such, mixture efficiency of the coolant may be improved.

Although the preferred embodiments of the present invention have been described above with reference to the accompanying drawings, those skilled in the art will appreciate that the present invention can be implemented in various other embodiments without changing the technical ideas or features thereof.

Hence, it should be understood that the embodiments described above are given by way of example in all aspects and are not intended to limit the present invention. The scope of the present invention should be defined by the claims, rather than the detailed description, and all modifications or modified forms derived from the meaning and scope of the claims and equivalents thereof should be construed as falling within the scope of the present invention.

What is claimed is:

1. A double-sided cooler for cooling both sides of a component, comprising:
a plurality of radiating parts including a plurality of cooling channels through which a coolant flows, the radiating parts being adhered to first and second sides of the component, respectively; and
a hollow connection part for mixing the coolant discharged from the cooling channels of one radiating part adhered to the first side side of the component to supply the mixed coolant to the cooling channels of another radiating part adhered to the second side of the component, the connection part being continuously formed from each radiating part to have the same shape of each radiating part to minimize pressure loss.

2. The double-sided cooler according to claim 1, wherein each of the radiating parts comprises a hollow radiating pipe adhered to the first or second sides of the component, and radiating plates dividing an inner space of the radiating pipe to form the cooling channels in a longitudinal direction of the radiating pipe.

3. The double-sided cooler according to claim 2, wherein each radiating plate is formed to be integrated with the radiating pipe and is formed to be perpendicular to a contact surface between the radiating pipe and component.

4. The double-sided cooler according to claim 2, wherein the radiating plate is formed to have a concave-convex shape by a repetition of an upper plate, a vertical plate and a lower plate, the radiating plate is inserted into the radiating pipe, the upper and lower plates being adhered to upper and lower surfaces in the radiating pipe, respectively, and each cooling channel is formed between the adjacent vertical plates.

5. The double-sided cooler according to claim 4, wherein the radiating plate is formed in a meandering bent shape to have a lateral zigzag shape in a longitudinal direction in order to increase a contact area for the coolant.

6. The double-sided cooler according to claim 3, wherein the vertical plate is formed to have a plurality of flow holes for the coolant to flow between each cooling channel.

7. The double-sided cooler according to claim 1, further comprising:
a coolant supply comprising a supply pipe receiving a cold coolant from a heat exchanger and a supply header supplying the coolant supplied from the supply pipe to the cooling channels of the radiating parts; and
a coolant discharger comprising a discharge header receiving the heated coolant from the radiating parts and a discharge pipe transferring the coolant supplied from the discharge header to the heat exchanger.

8. The double-sided cooler according to claim 7, wherein:
a plurality of the components is arranged in a multilayer structure;
the radiating parts are arranged between the components and on an outside of an outmost component;
the radiating parts are connected to one another in series through a plurality of the connection parts; and
the coolant supply and coolant discharger are connected to both ends of the radiating parts connected to one another in series.

9. The double-sided cooler according to claim 1, wherein the connection part is formed to have a plurality of protrusions and a plurality of grooves to generate vortex flow of the coolant introduced into the connection part and to mix the coolant.
